(19) United States
(12) Patent Application Publication
(10) Pub. No.: US 2022/0302366 A1
(43) Pub. Date: Sep. 22, 2022

(54) PIEZOELECTRIC TRANSDUCER

(71) Applicant: KISTLER HOLDING AG, WINTERTHUR (CH)

(72) Inventors: Marco Laffranchi, Winterthur (CH); David Weber, Seuzach (CH); Tobias Frommenwiler, Winterthur (CH); Andreas Wyss, Zuerich (CH)

(21) Appl. No.: 17/695,950

(22) Filed: Mar. 16, 2022

(30) Foreign Application Priority Data
Mar. 22, 2021 (EP) 21164057.8

(51) Int. Cl. H01L 41/047; H01L 41/053; H01L 41/113; H01L 41/25; H01L 41/23; H01L 41/29

(52) U.S. Cl. CPC H01L 41/0475; H01L 41/0533; H01L 41/1132; H01L 41/25; H01L 41/23; H01L 41/29; G01L 1/16

(57) ABSTRACT

A piezoelectric transducer includes a transducer unit disposed within a watertight and gas-tight housing and having at least one piezoelectric element contacted by at least two electrodes. A signal lead-through is electrically connected to the electrodes and configured conducting polarization charges as signals from the piezoelectric element through the housing to an environment outside of the housing. A signal cable arranged outside of the housing includes at least two signal conductors. The signal lead-through includes a support element having at least two conducting paths in electrical contact with one of the signal conductors.

### FIELD OF THE INVENTION

The present invention relates to a piezoelectric transducer for an acceleration sensor or a force sensor, and that includes a support element that facilitates transmission of electrical signals from piezoelectric elements inside the sensor to an evaluation unit that typically is disposed external to the sensor.

### BACKGROUND OF THE INVENTION

Commonly owned U.S. Pat. No. 3,313,962 discloses a piezoelectric transducer for use as a piezoelectric pressure transducer. It comprises at least one piezoelectric element made of a piezoelectric material. The piezoelectric element generates polarization charges under the influence of a measured variable to be detected. The number of polarization charges generated is proportional to the value of the measured variable. The polarization charges are tapped by electrodes and transmitted as signal.

The piezoelectric element is sensitive to and may easily undergo permanent damage due to environmental impacts such as contamination (dust, moisture, etc.). For this reason, the piezoelectric transducer comprises a housing made of a mechanically resistant material. The piezoelectric element and the electrodes are arranged in a water-tight and gas-tight manner in the interior of the housing.

The piezoelectric transducer further comprises a signal lead-through. The signal lead-through is mechanically connected to the housing and conducts the signal from the inside of the housing to the outside. For this purpose, the signal lead-through comprises at least one lead-through conductor that is electrically insulated from the housing. The lead-through conductor is electrically connected to at least one electrode inside the housing. The lead-through conductor can be electrically connected to at least one signal conductor of a signal cable outside of the housing.

A piezoelectric transducer of this type has a wide variety of applications. For example, a piezoelectric pressure transducer measures the pressure within the combustion chamber of an internal combustion engine. On the other hand, a piezoelectric force and torque transducer measures the joining force when joining components. In addition, a piezoelectric accelerometer measures the accelerations and vibrations of an object to which it is attached. A common feature of these diverse applications is that the piezoelectric transducer should be as small and as light as possible.

### OBJECTS AND SUMMARY OF THE INVENTION

It is a first object of the present invention to provide a piezoelectric transducer having small external dimensions and weight. Furthermore, a second object of the present invention is to provide a piezoelectric transducer manufactured at low cost. At least one of these objects is achieved by the features described below.

The invention relates to a piezoelectric transducer for measuring a measured variable; that comprises a transducer unit comprising at least one piezoelectric element and at least two electrodes, wherein said piezoelectric element is made of a piezoelectric material and generates polarization charges under the influence of said measured variable, wherein said electrodes contact the piezoelectric element directly in specific regions and tap the polarization charges; that comprises a housing which encloses the transducer unit in a water-tight and gas-tight manner; and that comprises a signal lead-through electrically connected to the electrodes and conducting the polarization charges as the signals through the housing to an environment located outside of the housing; wherein the piezoelectric transducer comprises a signal cable arranged in said environment outside of the housing and comprising at least two signal conductors; wherein said signal lead-through comprises a support element on which at least two conducting paths are arranged; and wherein each of the signal conductors contacts exactly one of said conducting paths.

The support element is a mechanical support for conducting paths wherein a contact is established between said conducting paths and the signal conductors of the signal cable. The support element and conducting paths may be fabricated with very small external dimensions. But still, the conducting paths on the support element are readily accessible for connection to the signal conductors.

Several further advantageous embodiments of the invention are described. For example, a procedure for the assembly the piezoelectric transducer as well as a procedure for incorporation of the support element in a piezoelectric transducer are described.

### BRIEF DESCRIPTION OF THE SEVERAL VIEWS OF THE DRAWINGS

In the following, the invention will be explained in more detail by way of example referring to the figures in which

FIG. 1 shows a schematic view of a section cut in the Y-Z plane in the direction of arrows designated A-A′ through a portion of a first embodiment of a piezoelectric transducer 1 of FIG. 17;

FIG. 2 shows a schematic view of a section cut in the Y-Z plane in the direction of arrows designated A-A′ through a portion of a second embodiment of a piezoelectric transducer 1 of FIG. 22;

FIG. 3 shows a schematic view of a section cut in the Y-Z plane in the direction of arrows designated A-A′ through a portion of a third embodiment of a piezoelectric transducer 1 of FIG. 17;

FIG. 4 shows a depiction of a schematic plan view of a first embodiment of a support element 13.1 of the piezoelectric transducer 1 according to FIG. 1;

FIG. 5 shows a schematic view from below of the first embodiment of the support element 13.1 according to FIG. 3;

FIG. 6 shows a depiction of a schematic plan view of a second embodiment of a support element 13.1 of the piezoelectric transducer 1 according to FIG. 2;

FIG. 7 shows a schematic view from below of the second embodiment of the support element 13.1 according to FIG. 6;

FIG. 8 shows a schematic view of a first embodiment of a support element 13.1 of the piezoelectric transducer 1 according to FIG. 3;

FIG. 9 shows a schematic depiction of a first step in the assembly of the first embodiment of the piezoelectric transducer 1 according to FIG. 1 in which a signal lead-through 13 comprising a signal lead-through wall 13.3 and a signal cable 14 is provided and ends of the signal cable 14 are inserted in a signal conductor opening 13.4 of the signal lead-through wall 13.3;

FIG. 10 shows a schematic depiction of a second step in the assembly according to FIG. 9 in which contacts between the signal conductors 14.11-14.14 of the signal cable 14 and the first embodiment of the support element 13.1 according to FIGS. 4 and 5 are established;

FIG. 11 shows a schematic depiction of a third step in the assembly according to FIGS. 9 and 10 in which the support element 13.1 is inserted in the signal feed-through wall 13.3;

FIG. 12 shows a schematic depiction of a fourth step in the assembly according to FIGS. 9 to 11 in which the support element 13.1 is cast with casting compound in the signal lead-through wall 13.3;

FIG. 13 shows a schematic depiction of a fifth step in the assembly according to FIGS. 9 to 12 in which parts of a housing 12 are provided and said parts of the housing 12 are secured to the signal lead-through wall 13.3;

FIG. 14 shows a schematic depiction of a sixth step in the assembly according to FIGS. 9 to 13 in which a transducer unit 11 is provided and secured within the housing 12;

FIG. 15 shows a schematic depiction of a seventh step in the assembly according to FIGS. 9 to 14 in which connecting conductors 13.31-13.34 are connected to the support element 13.1 and the transducer unit 11;

FIG. 16 shows a schematic view of an enlarged section of FIG. 15 showing the connecting conductor contact points 13.41-13.44 on the support element 13.1 and transducer unit contact surfaces 11.81-11.84 on the transducer unit 11 for establishing the contact by the connecting conductors 13.31-13.34;

FIG. 17 shows a schematic depiction of an eighth step in the assembly according to FIGS. 9 to 15 in which the housing opening is closed by a housing cover 12.3;

FIG. 18 shows a schematic depiction of the assembly of the embodiment of the piezoelectric transducer 1 according to FIG. 3 where in a first step parts of a housing 12, a signal lead-through 13 and a support element 13.1 in the embodiment according to FIG. 8 are provided and in a second step said parts of the housing 12 are secured to the signal lead-through wall 13.3 and the support element 13.1 is secured to a signal feedthrough wall 13.3 of the signal feedthrough 13;

FIG. 19 shows a schematic view of the assembly according to FIG. 18 where in a third step a signal cable 14 comprising signal conductors 14.11-14.14 is provided and the ends of the signal conductors 14.11-14.14 are inserted into a signal conductor opening 13.4 of the signal feed-through wall 13.3 and a through opening 13.4′ of the support element 13.1 and where in a fourth step contacts of the signal conductors 14.11-14.14 with signal conductor contact surfaces 13.131-13.134 of the support element 13.1 are established;

FIG. 20 shows a schematic depiction of a fifth step in the assembly according to FIGS. 18 and 19 in which the signal conductor opening 13.4′ of the support element 13.1 is cast with casting compound;

FIG. 21 shows a schematic view of the assembly according to FIGS. 18 to 20 where in a sixth step a transducer unit 11 is provided and said transducer unit 11 is secured within the housing 12 and where in a seventh step contacts of connecting conductors 13.31-13.34 with the support element 13.1 and the transducer unit 11 are established; and

FIG. 22 shows a schematic depiction of an eighth step in the assembly according to FIGS. 18 to 21 in which the housing opening is closed by a housing cover 12.3.

Throughout the figures, identical items are denoted by identical reference numerals. The accompanying drawings, which are incorporated in and constitute a part of this specification, illustrate at least one presently preferred embodiment of the invention as well as some alternative embodiments. These drawings, together with the written description, explain the principles of the invention but by no means are intended to be exhaustive of every possible embodiment of the invention.

### DETAILED DESCRIPTION OF EXEMPLARY EMBODIMENTS OF THE INVENTION

Reference will now be made in detail to present exemplary embodiments of the invention, wherein one or more examples of which are illustrated in the accompanying drawings. The detailed description uses numerical and/or letter designations to refer to features in the drawings. Like or similar designations in the drawings and description have been used to refer to like or similar parts of the embodiments of the invention.

Each example is provided by way of explanation of the invention, not limitation of the invention. In fact, it will be apparent to those skilled in the art that modifications and variations can be made in the present invention without departing from the scope or spirit thereof. For instance, features illustrated or described as part of one embodiment may be used on another embodiment to yield a still further embodiment. Thus, it is intended that the present invention covers such modifications and variations as come within the scope of the appended claims and their equivalents.

It is to be understood that the ranges and limits mentioned herein include all sub-ranges located within the prescribed limits, inclusive of the limits themselves unless otherwise stated. For instance, a range from 100 to 1200 also includes all possible sub-ranges, examples of which are from 100 to 150, 170 to 190, 153 to 162, 145.3 to 149.6, and 187 to 1200. Further, a limit of up to 7 also includes a limit of up to 5, up to 3, and up to 4.5, as well as all sub-ranges within the limit, such as from about 0 to 5, which includes 0 and includes 5 and from 5.2 to 7, which includes 5.2 and includes 7.

### Transducer Unit

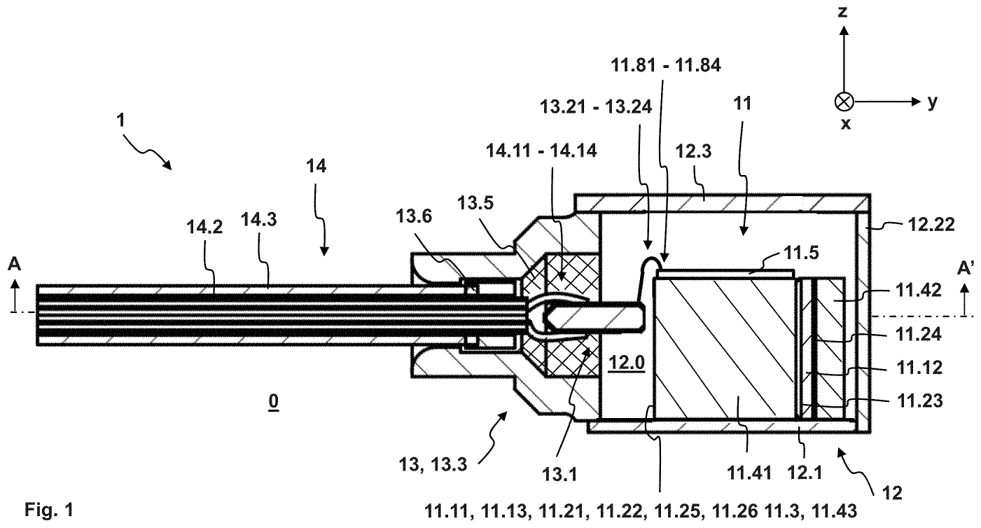

As schematically shown in a cross-sectional view in the Y-Z plane in FIG. 1 for example, the piezoelectric transducer 1 comprises a transducer unit 11, a housing 12, a signal lead-through 13, and a signal cable 14. For clarity, the piezoelectric transducer 1 is arranged in a rectangular coordinate system having three axes, x, y, z, designated as the transverse axis x, the longitudinal axis y and the vertical axis z.

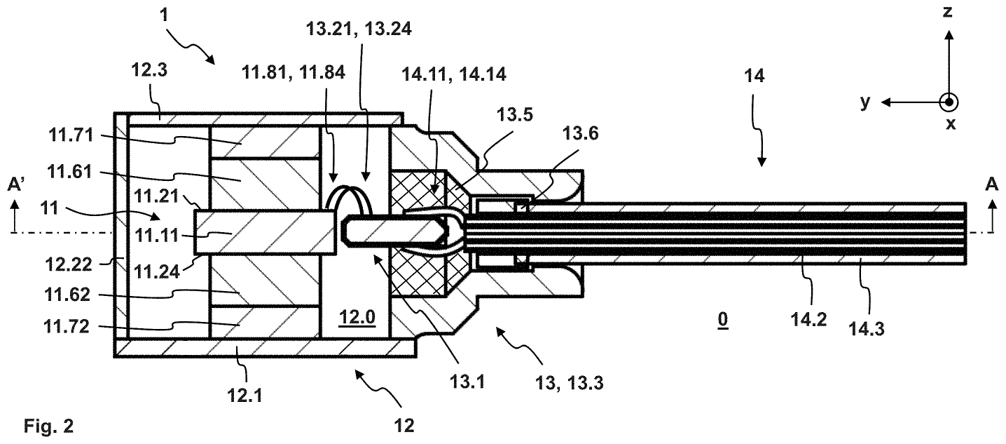

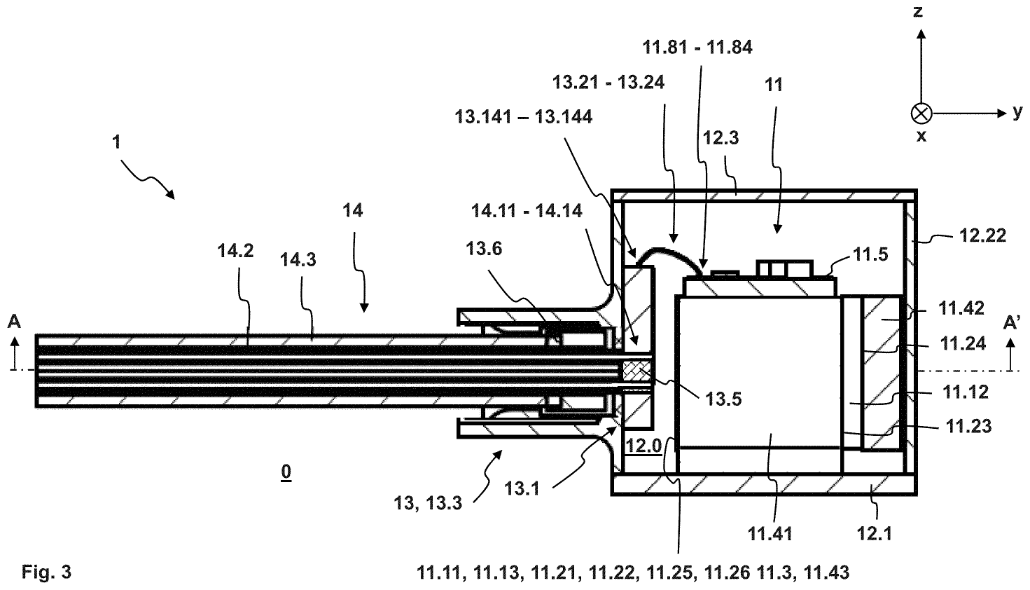

FIGS. 1 to 3 show three embodiments of the piezoelectric transducer 1. In the two embodiments according to FIGS. 1 and 3, the measured variable detected by the piezoelectric transducer 1 is accelerations. In the embodiment according to FIG. 2, the measured variables detected by the piezoelectric transducer 1 are pressures or forces or torques.

The transducer unit 11 comprises at least one piezoelectric element 11.11-11.13 made of a piezoelectric material. Examples of the piezoelectric material include quartz (SiO₂ single crystal), calcium gallo-germanate (Ca₃Ga₂Ge₄O₁₄ or CGG), langasite (La₃Ga₅SiO₁₄ or LGS), tourmaline, gallium orthophosphate, piezoceramics, etc.

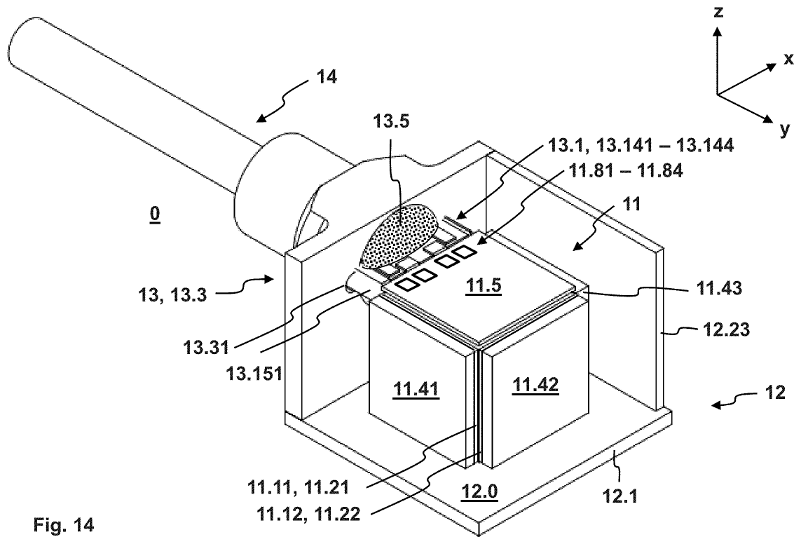

In the two embodiments of the piezoelectric transducer 1 as shown in FIGS. 1 and 3, the transducer unit 11 comprises three piezoelectric elements 11.11-11.13, i.e. a first piezoelectric element 11.11, a second piezoelectric element 11.12, and a third piezoelectric element 11.13. Each of these piezoelectric elements 11.11-11.13 has a rectangular cross-section in a plane that is normal to the direction of elongation of the central longitudinal axis designated A-A′ in FIGS. 1-3. The rectangular shapes of the piezoelectric elements 11.11, 11.12 and 11,13 also can be inferred from the perspective views of FIGS. 14, 15 and 21.

In the embodiment of the piezoelectric transducer 1 as shown in FIG. 2, the transducer unit 11 comprises one piezoelectric element 11.11. The piezoelectric element 11.11 has a disc-shaped cross-section and is defined as a truncated cylinder that has two flat surfaces joined by a portion defined by an edge that is shaped like a right cylinder for example.

The transducer unit 11 comprises at least two electrodes 11.21, 11.22, and desirably there are six electrodes 11.21, 11.22, 11.23, 11.24, 11.25 and 11.26. Each of the electrodes 11.21-11.26 is made of an electrically conductive material. Examples of the electrically conductive material include copper, copper alloys, gold, gold alloys, aluminum, aluminum alloys, silver, silver alloys, etc. Each piezo element 11.11-11.13 generates polarization charges under the influence of a measured variable to be measured. These polarization charges are picked up by the electrodes 11.21-11.26. Each one of the electrodes 11.21-11.26 directly contacts one of two opposite surfaces of one of the piezo elements 11.11-11.13 in specific regions of the respective piezo element. In the context of the present invention, the verb “to contact” means to provide an electrical and mechanical connection. In addition, the adverb “directly” has the meaning of “immediately”. Preferably, each of the electrodes 11.21-11.26 has a thickness of less than/equal to 0.1 mm. Each of the electrodes 11.21-11.26 consists of thermo-laminated films, metal depositions, and the like.

The transducer unit 11 comprises at least one first electrode 11.21-11.23 and at least one further electrode 11.24-11.26. Each respective first electrode 11.21, 11.22, 11.23 is paired with a respective further electrode 11.24, 11.25, 11.26 and assigned to a respective one of the piezoelectric elements 11,11, 11,12, 11,13.

In the two embodiments of the piezoelectric transducer 1 as shown in FIGS. 1 and 3, the transducer unit 11 comprises three first electrodes 11.21-11.23 and three further electrodes 11.24-11.26. Each of the three first electrodes 11.21-11.23 picks up polarization charges from the respective piezoelectric element 11.11-11.13 and provides one of three first signals S1-S3. Each further electrode 11.24-11.26 taps polarization charges from the piezo element 11.11-11.13. The further electrodes 11.24-11.26 are electrically short-circuited to form a common signal ground. The signal ground S4 is supplied as a further signal S4.

In the embodiment of the piezoelectric transducer 1 as shown in FIG. 2, the transducer unit 11 comprises a first electrode 11.21 and a further electrode 11.24. The first electrode 11.21 picks up polarization charges from the piezoelectric element 11.11 and provides a signal S1. The further electrode 11.24 picks up polarization charges from the piezoelectric element 11.11 and provides a further signal S4.

In the two embodiments of the piezoelectric transducer 1 as shown in FIGS. 1 and 3, the transducer unit 11 comprises a base body 11.3. The base body 11.3 is preferably made of a mechanically rigid material having a low density such as Al₂O₃, ceramics, Al₂O₃ ceramics, sapphire, etc. Preferably, the base body 11.3 has the shape of a cube having six faces. The transducer unit 11 is attached to the housing base 12.1 via one of the six faces of the base body 11.3.

In the two embodiments of the piezoelectric transducer 1 as shown in FIGS. 1 and 3, the transducer unit 11 comprises three seismic masses 11.41-11.43. The seismic masses 11.41-11.43 are preferably made of a material having a high density such as iridium, platinum, tungsten, gold, etc. Each seismic mass 11.41-11.43 has a rectangular cross-section. A first seismic mass 11.41 and the first piezoelectric element 11.1 are attached to a first face of the base body 11.3. As shown in FIGS. 1 and 3, a second seismic mass 11.42 and the second piezoelectric element 11.12 are attached to a second face of the base body 11.3. A third seismic mass 11.43 and the third piezoelectric element 10.13 are attached to a third face of the base body 11.3. For this purpose, each respective piezoelectric element 11.11-11.13 is arranged between a respective one of the faces of the base body 11.3 and a respective seismic mass 11.41-11.43.

In the two embodiments of the piezoelectric transducer 1 as shown in FIGS. 1 and 3, the transducer unit 11 comprises at least one converter unit 11.5. The converter unit 11.5 is an electrical circuit and converts at least the first signals S1-S3. The conversion of the first signals S1-S3 comprises at least one of the following: an electrical conversion of the first signals S1-S3 into an electrical voltage, an electrical amplification of the first signals S1-S3, a digitization of the first signals S1-S3. As shown in FIGS. 1 and 3, the converter unit 11.5 is secured to one of the six faces of the base body 11.3 that is not secured to a piezoelectric element 11.11-11.13.

The transducer unit 11 comprises at least two transducer unit contact surfaces 11.81-11.84. Signals S1-S4 are applied to the transducer unit contact surfaces 11.81-11.84.

In the two embodiments of the piezoelectric transducer 1 as shown in FIGS. 1 and 3, the converter unit 11.5 of the transducer unit 11 comprises three first transducer unit contact surfaces 11.81-11.83 and one further transducer unit contact surface 11.84. First signals S1-S3 are applied to the three first transducer unit contact surfaces 11.81-11.83 as the converted first signals S1-S3, and the further signal S4 is applied to the further transducer unit contact surface 11.84.

In the embodiment of the piezoelectric transducer 1 according to FIG. 2, the first electrode 11.21 of the transducer unit 11 comprises a first transducer unit contact surface 11.81, and the further electrode 11.24 of the transducer unit 11 comprises a further transducer unit contact surface 11.84. The first signal S1 is applied to the first transducer unit contact surface 11.81, and the further signal S4 is applied to the further transducer unit contact surface 11.84.

In the embodiment of the piezoelectric transducer 1 according to FIG. 2, the transducer unit 1 comprises a first insulation element 11.61 and a second insulation element 11.62. The insulation elements 11.61, 11.62 are preferably made of a mechanically rigid material having a low density such as Al₂O₃, ceramics, Al₂O₃ ceramics, sapphire, and the like. Preferably, the insulating elements 11.61, 11.62 are cylindrical in shape. One of the flat end surfaces of each of the insulation elements 11.61, 11.62 abuts on the outer flat surface of one of the electrodes 11.21, 11.24 in alignment along the vertical axis z as schematically shown in FIG. 2. The insulation elements 11.61, 11.62 are disposed to provide electrical insulation of the piezo element 11.11 and the electrodes 11.21, 11.24 from the housing 12.

In the embodiment of the piezoelectric transducer 1 as shown in FIG. 2, the transducer unit 11 comprises a first compensation element 11.71 and a second compensation element 11.72. The compensation elements 11.71, 11.72 are preferably made of a mechanically rigid material such as pure metals, nickel alloys, cobalt alloys, iron alloys, and the like. The compensation elements 11.71, 11.72 serve to provide compensation of different coefficients of thermal expansion of the piezo element 11.11, the electrodes 11.21, 11.24 and the housing 12. Preferably, the compensation elements 11.71, 11.72 are cylindrical in shape. One of the flat ends of each of the compensation elements 11.71, 11.72 abuts on the outer flat end surface of one of the insulation elements 11.61, 11.62 in alignment along the vertical axis z as schematically shown in FIG. 2. The transducer unit 11 is secured to the housing 12 via the compensation elements 11.71, 11.72.

### Housing

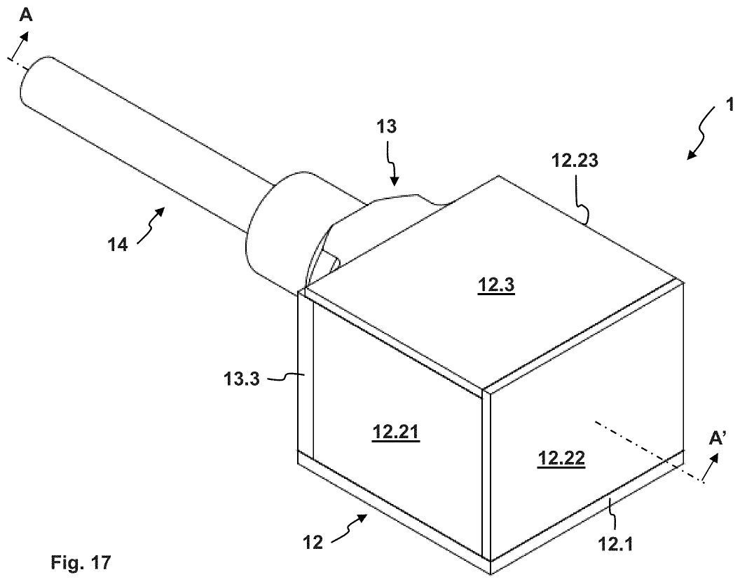

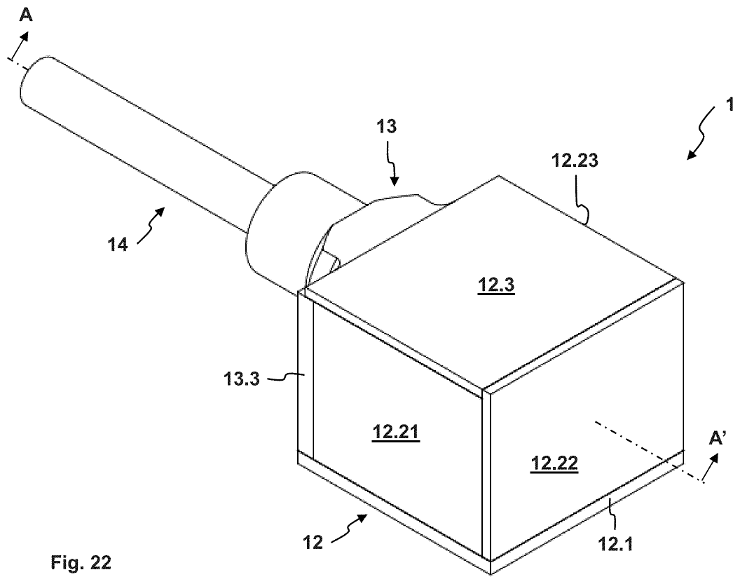

The housing 12 protects the transducer unit 11 from adverse environmental impacts such as contamination (dust, moisture, etc.) but also from electrical and electromagnetic interference effects in the form of electromagnetic radiation originating in an environment. The housing 12 is made of a mechanically resistant material such as pure metals, nickel alloys, cobalt alloys, iron alloys, and the like. The housing 12 is a hollow body that defines a housing interior 12.0. Preferably, the housing 12 consists of distinct parts which are a housing base 12.1, at least one housing wall 12.21-12.23 and a housing cover 12.3. Preferably, the housing 12 comprises three housing walls 12.21-12.23, i.e. a first housing wall 12.21, a second housing wall 12.22 and a third housing wall 12.23. Only the second housing wall 12.22 is shown in the sections according of FIGS. 1 to 3. However, the depictions according to FIGS. 17 and 22 show all three housing walls 12.21-12.23. The parts of the housing 12 are connected to each other in a mechanically stable manner by means of material bonding such as welding, soldering, adhesive bonding, and the like. In the three embodiments as shown in FIGS. 1 to 3, the housing 12 has the shape of a cuboid having six side walls. Five side walls of these six side walls are formed by the housing base 12.1, the three housing walls 12.21-12.23 and the housing cover 12.3. The sixth side wall is formed by a signal lead-through wall 13.3 of the signal lead-through 13.

The size of the housing interior 12.0 is such that the transducer unit 11 can be completely accommodated therein. The transducer unit 11 can be inserted into the housing interior 12.0 through a housing opening. The housing opening can be closed by the housing cover 12.3. Preferably, the housing 12 is grounded. The piezoelectric transducer 1 that is grounded by the housing 12 has the electrical potential of the local ground. Thus, housing 12 forms a Faraday's cage against electromagnetic radiation from the environment 0.

### Signal Lead-Through

The signal lead-through wall 13.3 is made of a mechanically resistant material such as pure metals, nickel alloys, cobalt alloys, iron alloys, and the like. The signal lead-through wall 13.3 is secured to the housing 12 by material bonding such as welding, soldering, adhesive bonding, and the like to the housing 12 in a mechanically stable manner. The signal lead-through wall 13.3 comprises a first surface and a second surface, which is disposed in opposition to the first surface. When the signal lead-through wall 13.3 is connected to the housing 12 in a mechanically stable manner, the first surface delimits the piezoelectric transducer 1 against the environment 0 and the second surface delimits the housing interior 12.0. The environment 0 is located on the outside of the housing 12. The housing 12 together with the signal lead-through wall 13.3 connected thereto in a mechanically stable manner enclose the transducer unit 11 in a water-tight and gas-tight manner with respect to the environment 0. In this way, the housing 12 is configured to be able to withstand a water or gas pressure of at least 3 bars.

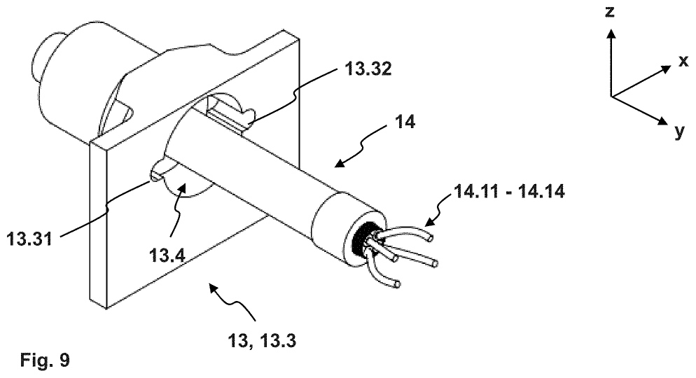

As schematically shown in FIGS. 9-13 for example, the signal lead-through wall 13.3 comprises a signal conductor opening 13.4. The signal conductor opening 13.4 extends from the first surface to the second surface through the signal lead-through wall 13.3. Preferably, the cross-section of the signal conductor opening 13.4 matches that of the signal cable 14. Ends of the signal conductors 14.11-14.14 protrude through the signal conductor opening 13.4 into the interior of the housing 12.0.

As schematically shown in FIGS. 1-3 for example, the signal lead-through 13 comprises a signal lead-through flange 13.6. The signal lead-through flange 13.6 delimits the signal conductor opening 13.4 on one side. Preferably, one end of the protective sheath 14.3 of the signal cable 14 is connected to the signal lead-through flange 13.6. The connection of the protective sheath 14.3 and the signal lead-through flange 13.6 is achieved by a frictional connection such as crimping, and the like. The connection of the protective sheath 14.3 and the signal lead-through flange 13.6 is water-tight and gas-tight against the environment 0. The connection of the protective sheath 14.3 and the signal lead-through flange 13.6 provides strain relief of the protective sheath 14.3. This strain relief of the protective sheath 14.3 prevents mechanical stresses to be transmitted from the protective sheath 14.3 into the housing interior 12.0 where they could cause damage such as tearing off of or causing fissures in connecting conductors 13.21-13.24. Such mechanical stresses originate from twisting, torsion, etc. of the protective sheath 14.3 about its longitudinal direction axis designated A-A′ in FIGS. 1-3.

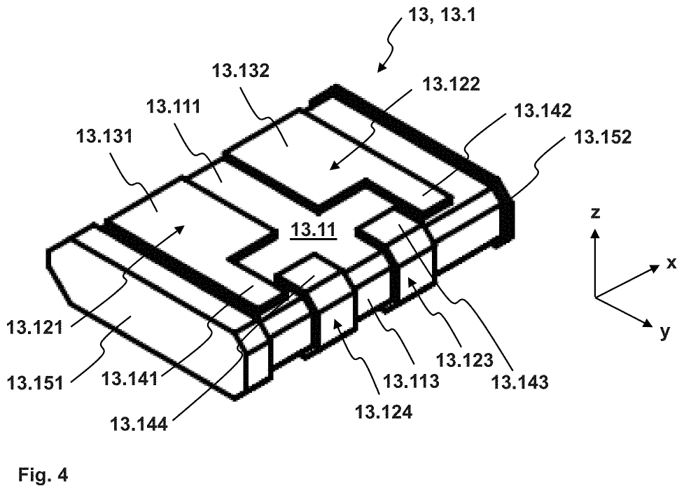

The signal lead-through 13 comprises a support element 13.1. FIGS. 4 to 8 show three embodiments of the support element 13.1.

In the two embodiments as shown in FIGS. 4 to 7, the largest axial extension of the support element 13.1 preferably is along the transverse axis x and largely corresponds to the cross-section of the signal cable 14. A second largest axial extension of the support element 13.1 extends along the longitudinal axis y. A smallest axial extension of the support element 13.1 extends along the vertical axis z.

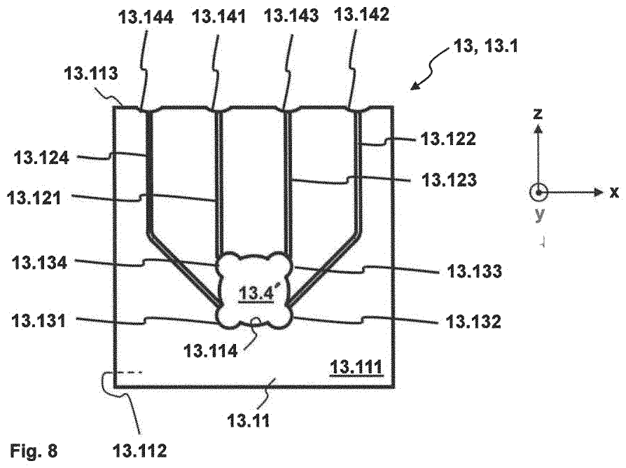

In the embodiment according to FIG. 8, the support element 13.1 preferably has two largest axial extensions along the transverse axis x and the vertical axis z. A smallest axial extension of the support element 13.1 extends along the longitudinal axis y.

Preferably, the support element 13.1 is shaped as a cuboid having six faces. The faces are different in size. Two of the six faces extend parallel to the largest axial extension and the second largest axial extension of the support element 13.1. They have the largest surface area as compared to the other four faces. They are referred to as the first end face 13.111 and the further end face 13.112, which is disposed in opposition to the first end face 13.111. The other four faces are adjacent to both the first end face 13.111 and the further end face 13.112 forming an area of transition between the first end face 13.111 and the further end face 13.112. One of the four faces is called the lateral surface 13.113.

The support element 13.1 comprises a body 13.11 made of an electrically insulating material such as Al₂O₃, ceramics, Al₂O₃ ceramics, fiber-reinforced plastics, and the like. Preferably, said fiber-reinforced plastic is a flame-resistant and flame-retardant composite material of an epoxide resin and fiberglass fabric such as Flame Retardant (FR-4).

In the third embodiment according to FIG. 8, the support element 13.1 comprises a through opening 13.4′. Through opening 13.4′ extends from the first end face 13.111 to the further end face 13.112 along the longitudinal axis y. Preferably, the through opening 13.4′ has a cross-section that corresponds to that of the signal cable 14. The through opening 13.4′ is defined by an inner surface 13.114. The inner surface 13.114 forms a transition area from the first end surface 13.111 to the further end surface 13.112.

Several conducting paths 13.121-13.124 are defined on external surfaces of the support element 13.1. The conducting paths 13.121-13.124 are arranged directly on the body 13.11. Preferably, the conducting paths 13.121-13.124 are patterned in the form of an electrically conductive thin film that is applied directly to the body 13.11. The electrically conductive thin film consists of a thermo-laminated metal film or is achieved by metal deposition. The metal that may be used to form the conducting paths 13.121-13.124 includes copper, copper alloys, gold, gold alloys, platinum, platinum alloys, and the like. The metal deposition desirably is performed by chemical vapor deposition, physical vapor deposition, and the like. The term “thin film” in the context of the present invention refers to a thickness in a direction perpendicular to the planar extension of preferably less than or equal to 0.1 mm. The patterning of the conducting paths 13.121-13.124 is preferably achieved by stencils, photolithography and laser ablation.

Preferably, the conducting paths 13.121-13.124 extend parallel to each other in a specific area of the support element 13.1. In this area of the support element 13.1, a mutual distance of the conducting paths 13.121-13.124 is preferably less than or equal to 0.3 mm.

Each conducting path 13.121-13.124 preferably defines a region that is a first end and further defines a region that is a second end, which is disposed spaced apart from and generally opposite the first end. A signal conductor contact surface 13.131-13.134 is located at the first end, and a connecting conductor contact surface 13.141-13.144 is located at the second end.

The support element 13.1 comprises at least one first conducting path 13.121-13.123 and at least one further conducting path 13.124.

In the two embodiments of the support element 13.1 according to FIGS. 4, 5 and 8, the support element 13.1 comprises three first conducting paths 13.121-13.123 each having a first signal conductor contact surface 13.131-13.133 and a first connecting conductor contact surface 13.141-13.143, and one further conducting path 13.124 having a further signal conductor contact surface 13.134 and a further connecting conductor contact surface 13.144.

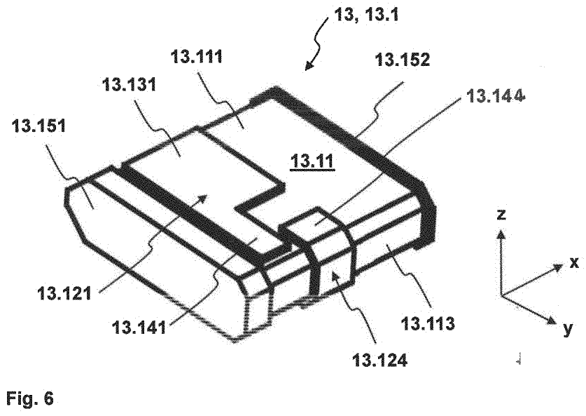

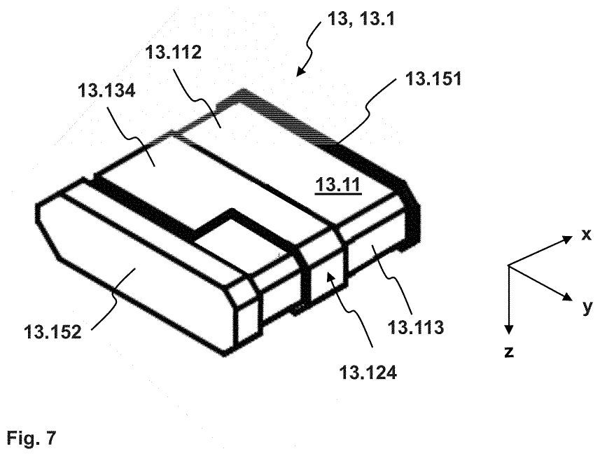

In the embodiment of the support element 13.1 according to FIGS. 6 and 7, the support element 13.1 comprises a first conducting path 13.121 having a first signal conductor contact surface 13.131 and a first connecting conductor contact surface 13.141, and a further conducting path 13.124 having a further signal conductor contact surface 13.134 and a further connecting conductor contact surface 13.144.

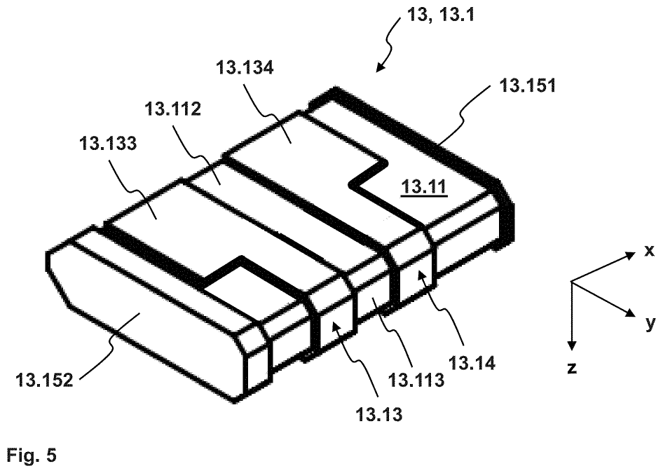

In the first embodiment of the support element 13.1 according to FIGS. 4 and 5, two first conducting paths 13.121, 13.122 are arranged completely on the first end face 13.111. However, a pair of wrap-around conducting paths is formed by a first conducting path 13.123 and the further conducting path 13.124, each of which is contiguously arranged partially on the first end face 13.111, partially on the lateral surface 13.113 and partially on the further end face 13.112. Two first signal conductor contact surfaces 13.131, 13.132 and all four connecting conductor contact surfaces 13.141-13.144 are arranged on the first end face 13.111. However, though not visible in the view of FIG. 4, FIG. 5 depicts the opposite end face 13.112 of this embodiment and shows that one first signal conductor contact surface 13.133 and the further signal conductor contact surface 13.134 are arranged on the second end face 13.112.

In the second embodiment of the support element 13.1 according to FIGS. 6 and 7, the first conducting path 13.121 is arranged completely on the first end face 13.111, and the further conducting path 13.124 is a wrap-around conducting path that is contiguously arranged partially on the first end face 13.111, partially on the lateral surface 13.113 and partially on the further end face 13.112. The first signal conductor contact surface 13.131 and all of the two connecting conductor contact surfaces 13.141, 13.144 are arranged on the first end face 13.111 as shown in FIG. 6, and the further signal conductor contact surface 13.134 is arranged on the second end face 13.112 as shown in FIG. 7.

In the third embodiment of the support element 13.1 according to FIG. 8, all four conductor paths 13.121-13.124 are arranged on the first end face 13.111. All four connecting conductor contact surfaces 13.141-13.144 are arranged on the lateral surface 13.113. Preferably, the connecting conductor contact surfaces 13.141-13.144 are formed as notches in the lateral surface 13.113. Furthermore, all four signal conductor contact surfaces 13.131-13.134 are arranged on the inner surface 13.114. Preferably, the signal conductor contact surfaces 13.131-13.134 are formed as notches in the inner surface 13.114.

In the two embodiments according to FIGS. 4 to 7, the support element 13.1 comprises at least one guiding element 13.151, 13.152. Preferably, the support element 13.1 comprises two ends along its greatest axial extension along the transverse axis x. A first guiding element 13.151 is located at the first end, and a second guiding element 13.152 is located at the second end. The longest dimensions of the guiding elements 13.151, 13.152 extend along the longitudinal axis y. Preferably, each of the guiding elements 13.151, 13.152 is formed as a ridge at the body 13.11. The ridge has a constant outer radius with respect to a terminal edge of the body 13.11 that extends along the longitudinal axis y. Preferably, the guiding elements 13.151, 13.152 are patterned in an electrically conductive thin film applied directly to the body 13.11. Preferably, the guiding elements 13.151, 13.152 have a thickness of less than or equal to 0.1 mm.

In a first embodiment of the signal lead-through wall 13.3 according to FIGS. 9 to 17, the support element 13.1 is retained in the signal lead-through opening 13.4. For this purpose, the signal lead-through wall 13.3 defines a feature that functions as at least one holding element 13.31, 13.32. Preferably, the signal lead-through wall 13.3 defines two holding elements 13.31, 13.32 shaped as grooves in the circumference of the signal conductor opening 13.4. The ridge-shaped guiding elements 13.151, 13.152 and the holding means 13.31, 13.32 formed as grooves are fabricated to match each other in a complementary manner. The support element 13.1 can be inserted into the holding elements 13.31, 13.32 by the guiding elements 13.151, 13.152. The size of an inner radius of the groove-shaped holding elements 13.31, 13.32 along the longitudinal axis y corresponds to that of the outer radius of the ridge-shaped guiding elements 13.151, 13.152. The support element 13.1 is retained in the signal lead-through wall 13.3 by inserting the guiding element 13.151, 13.152 into the holding element 13.31, 13.32. Preferably, it is retained by positive engagement. This retaining prevents the inserted support element 13.1 from dropping out of the signal lead-through wall 13.3. The inserted support element 13.1 is retained by the holding element 13.31, 13.32 in a defined holding position. The guiding elements 13.151, 13.152 and the holding means 13.31, 13.32 are metallic and, thus, an electrical contact is created when the support element 13.1 is held by the holding elements 13.31, 13.32.

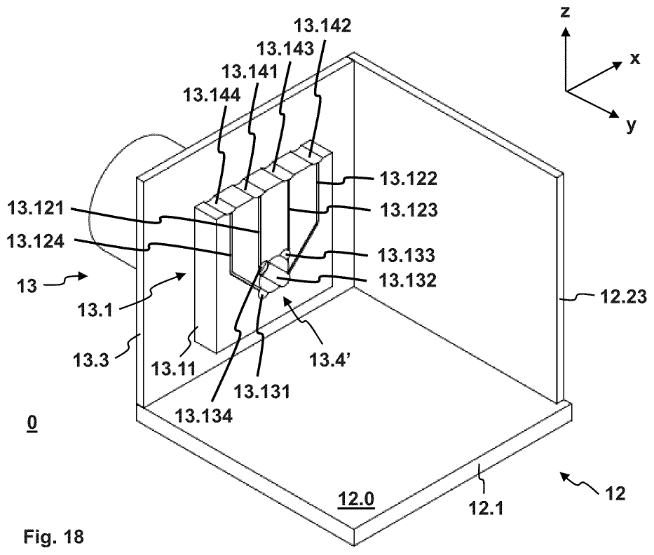

In a second embodiment of the signal lead-through wall 13.3 according to FIGS. 18 to 22, the support element 13.1 is attached to the signal lead-through wall 13.3. Preferably, said attachment is achieved by material bonding by means of an adhesive consisting of epoxide, polyurethane, cyanoacrylate, methyl methacrylate, and the like. The support element 13.1 is attached to the second surface of the signal lead-through wall 13.3 via its further end face 13.112. The arrangement of the support element 13.1 on the signal lead-through wall 13.3 is such that the signal conductor opening 13.4 through the signal lead-through wall 13.3 coincides with the through opening 13.4′ that is defined through the support element 13.1.

When the signal lead-through wall 13.3 is connected to the housing 12 in a mechanically stable manner, it is preferably grounded, i.e. the signal lead-through wall 13.3 and the housing 12 have the electrical potential of the local ground. Thus, the signal lead-through wall 13.3 and the housing 12 form a Faraday's cage against electromagnetic radiation from the environment 0.

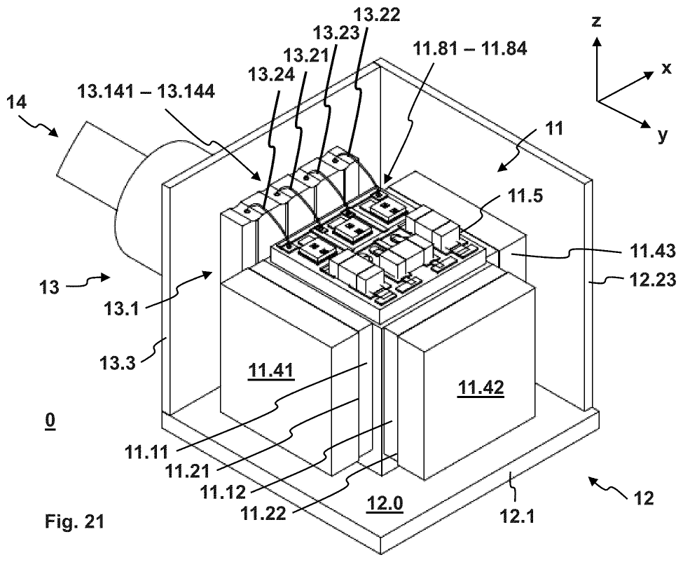

As shown in FIG. 21, the signal lead-through 13 comprises at least two connecting conductors 13.21-13.24. The connecting conductors 13.21-13.24 desirably have a diameter of less than or equal to 0.5 mm. The connecting conductors 13.21-13.24 conduct the signals S1-S4 from the transducer unit 11 to the signal lead-through 13. At least one first connecting conductor 13.21-13.23 transmits first signals S1-S3, and at least one second connecting conductor 13.24 transmits a further signal S4. Each connecting conductor 13.21-13.24 comprises a first end and a second end. The connecting conductors 13.21-13.24 establish contacts to the transducer unit 11 and the signal lead-through 13. Preferably, the contacts are achieved by a material connection such as wire bonding, soldering, and the like. Suitable procedures for wire bonding include thermocompression bonding, thermosonic ball wedge bonding, ultrasonic wedge-wedge bonding, and the like.

In the two embodiments of the piezoelectric transducer 1 according to FIGS. 1 and 3, each first connecting conductor 13.21-13.23 contacts exactly one first transducer unit contact surface 11.81-11.83 by its first end, and each first connecting conductor 13.21-13. 23 contacts exactly one first connecting conductor contact surface 13.141-13.143 by its second end. The further connecting conductor 13.24 contacts the further transducer unit contact surface 11.84 by its first end, and the further connecting conductor 13.24 contacts the further connecting conductor contact surface 13.144 by its second end.

In the embodiment of the transducer unit 11 according to FIG. 2, the first connecting conductor 13.21 contacts the first transducer unit contact surface 11.81 by its first end, and the first connecting conductor 13.21 contacts the first connecting conductor contact surface 13.141 by its second end. Furthermore, the further connecting conductor 13.24 contacts the further transducer unit contact surface 11.84 by its first end, and the further connecting conductor 13.24 contacts the further connecting conductor contact surface 13.144 by its second end.

### Signal Cable

As generally shown in FIGS. 1-3, the signal cable 14 is secured in specific areas to the signal lead-through 13. The signal cable 14 is located in the environment 0 outside of the housing 12. The signal cable 14 comprises at least two signal conductors 14.11-14.14, a cable insulation 14.2, and a protective sheath 14.3.

In the first embodiment of the signal lead-through wall 13.3 according to FIGS. 9 to 17, ends of the signal conductors 14.11-14.14 protrude through the signal conductor opening 13.4 into the housing interior 12.0.

In a second embodiment of the signal lead-through wall 13.3 in combination with the third embodiment of the support element 13.1 according to FIGS. 18 to 22, ends of the signal conductors 14.11-14.14 protrude through the signal conductor opening 13.4 into the through opening 13.4′ within the housing interior 12.0.

The signal conductors 14.11-14.14 are made of an electrically conductive material such as copper, copper alloys, gold, gold alloys, aluminum, aluminum alloys, and the like. Preferably, each signal conductor 14.11-14.14 comprises an electrically insulating sheath. The signal conductors 14.11-14.14 have a diameter of less than or equal to 0.5 mm.

The signal cable 14 comprises at least one first signal conductor 14.11-14.13 and at least one further signal conductor 14.14. In the two embodiments of the piezoelectric transducer 1 according to FIGS. 1 and 3, the signal cable 14 comprises three first signal conductors 14.11-14.13 and one further signal conductor 14.14. In the embodiment of the piezoelectric transducer 1 according to FIG. 2, the signal cable 14 comprises a first signal conductor 14.11 and a further signal conductor 14.14.

As schematically shown in FIGS. 1-3, the cable insulation 14.2 completely surrounds the signal conductors 14.11-14.14 circumferentially with respect to the central longitudinal axis designated A-A′. The cable insulation 14.2 insulates the signal conductors 14.11-14.14 electrically from the protective sheath 14.3. The cable insulation 14.2 is made of an electrically insulating material such as Al₂O₃, ceramics, Al₂O₃ ceramics, fiber-reinforced plastics, and the like.

The protective sheath 14.3 surrounds the cable insulation 14.2 in a radial direction in a water-tight and gas-tight manner against the environment 0. The protective sheath 14.3 protects the cable insulation 14.2 as well as the signal conductors 14.11-14.14 from adverse environmental impacts such as contamination (dust, moisture, and the like) as well as from electromagnetic waves. The protective sheath 14.3 is made of a mechanically resistant material such as metal, plastics, and the like.

Each of the signal conductors 14.11-14.14 of the signal cable 14 contacts exactly one of the conducting paths 13.121-13.124 of the support element 13.1. The contact functions to provide electrical transmission and preferably is achieved by a material connection such as soldering, conductive bonding, wire bonding, and the like. One end of the at least one first signal conductor 14.11-14.13 contacts the at least one first signal conductor contact surface 13.131-13.133 and one end of the at least one further signal conductor 14.14 contacts the at least one further signal conductor contact surface 13.134.

In the third embodiment of the support element 13.1 according to FIGS. 8 and 18 to 22, the signal conductor contact surfaces 13.131-13.134 are formed as notches in the inner surface 13.114 of the through opening 13.4′. The notches have a diameter that largely corresponds to the diameter of the signal conductors 14.11-14.14. Thus, the signal conductors 14.11-14.14 arranged on the signal conductor contact surfaces 13.131-13.134 are held by the notches in a positive-locking connection.

Signals S1-S4 are transmitted via the conducting paths 13.121-13.124 of the support element 3.1 to the signal conductors 14.11-14.14 of the signal cable 14. Preferably, the signals S1-S4 are transmitted in a manner insulated from ground. The term “insulated from ground” in the context of the present invention means electrically insulated with respect to the grounding of the piezoelectric transducer 1.

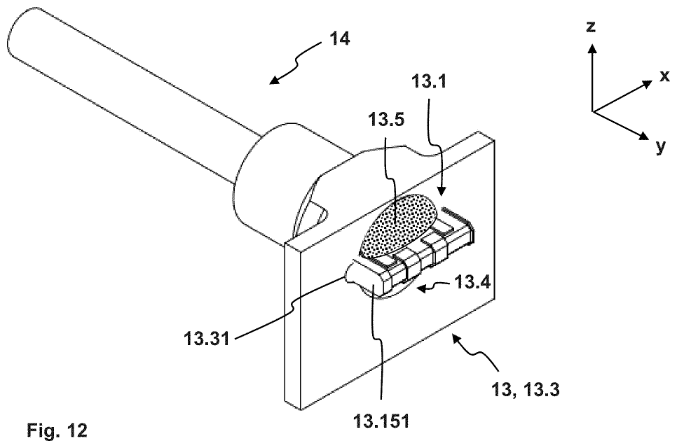

As shown schematically in FIGS. 12-16, the signal lead-through 13 comprises a casting compound 13.5. The casting compound 13.5 is a chemically curing adhesive or a physically setting adhesive or a combination of a chemically curing adhesive and a physically setting adhesive. Preferably, the casting compound 13.5 consists of an adhesive such as epoxide, polyurethane, cyanoacrylate, methyl methacrylate, and the like. The casting compound 13.5 is an electrical insulator having an electrical resistivity of more than 10¹² Ωmm²/m. Preferably, in the first embodiment of the signal lead-through wall 13.3 according to FIGS. 9 through 17, the amount of casting compound 13.5 applied to the signal conductors 14.11-14.14 in the signal conductor opening 13.4 is such that the signal conductor opening 13.4 is completely sealed.

The casting compound 13.5 is further applied in specific areas to the support element 13.1 and to the signal lead-through wall 13.3 in the signal conductor opening 13.4. The cured and/or set casting compound 13.5 on the support element 13.1 and on the signal lead-through wall 13.3 mechanically secures the support element 13.1 that is inserted in the signal lead-through wall 13.3 in a holding manner. Moreover, the cured and/or set casting compound 13.5 seals the signal conductor opening 13.4 in a water-tight and gas-tight manner.

In a second embodiment of the signal lead-through wall 13.3 in combination with the third embodiment of the support element 13.1 according to FIGS. 18 to 22, the amount of casting compound 13.5 applied to the signal conductors 14.11-14.14 in the through opening 13.4′ is preferably such that the through opening 13.4′ is completely sealed. The cured and/or set casting compound 13.5 seals the through-opening 13.4′ in a water-tight and gas-tight manner.

This water-tight and gas-tight seal prevents moisture from penetrating into the housing interior 12.0 via the signal conductors 14.11-14.14 and from reaching the piezoelectric element 11.11-11.13 where moisture might impair functioning of the piezoelectric element 11.11-11.13 since piezoelectric material such as quartz is strongly hygroscopic.

After the casting compound 13.5 is cured and/or set, it secures the signal conductors 14.11-14.14 in a strain-relieved manner. This strain relief of the signal conductors 14.11-14.14, prevents mechanical stresses from being transmitted from the signal conductors 14.11-14.14 into the interior of the housing 12.0 where they might cause damage such as a tearing off of or leading to fissures in connecting conductors 13.21-13.24. Such mechanical stresses originate from twisting, torsion, and the like of the signal conductors 14.11-14.14 about their longitudinal direction axis.

### Assembly Procedure

The assembly of the piezoelectric transducer 1 is performed in a plurality of steps.

Assembly of the first embodiment of the piezoelectric transducer 1 according to FIG. 1 is shown schematically in the views according to FIGS. 9 to 17 and described in the following:

FIG. 9 schematically shows a first step of the assembly in which the signal lead-through 13 with the signal lead-through wall 13.3 and the signal cable 14 with the signal conductors 14.11-14.14 are provided. The signal lead-through wall 13.3 defines a signal conductor opening 13.4.

Ends of the signal conductors 14.11-14.14 are stripped of any insulation down to the bare metal. The stripped ends of the signal conductors 14.11-14.14 are inserted through the signal conductor opening 13.4 from the side where the environment 0 is located. The stripped ends of the signal conductors 14.11-14.14 protrude through the signal conductor opening 13.4.

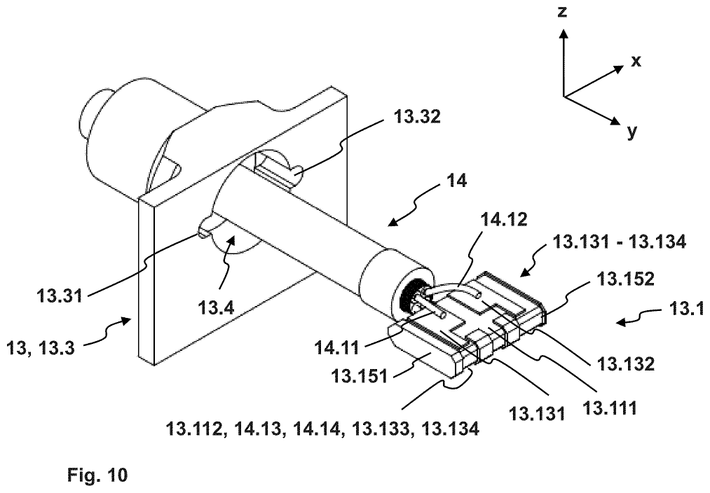

FIG. 10 schematically shows a second step of the assembly in which the support element 13.1 with at least two conducting paths 13.121-13.124 on end faces 13.111, 13.112 is provided. The conducting paths 13.121-13.124 terminate in signal conductor contact surfaces 13.131-13.134.

The support element 13.1 is positioned in the signal conductor opening 13.4 such that the ends of the signal conductors 14.11-14.14 protrude onto the end faces 13.111, 13.112. The end of the at least one first signal conductor 14.11-14.13 protrudes onto the first end face 13.111, and the end of the at least one further signal conductor 14.14 protrudes onto the further end face 13.112. The term “protrude onto” in the context of the present invention refers to a spatial position of the ends of the signal conductors 14.11-14.14 at a distance along the vertical axis z of less than or equal to 1 mm, preferably less than or equal to 0.5 mm from the signal conductor contact surfaces 13.131-13.134. The depiction shown in FIG. 10 of the first embodiment of the piezoelectric transducer 1 according to FIG. 1 only shows the ends of two first signal conductors 14.11, 14.12 protruding onto two first signal conductor contact surfaces 13.131, 13.132 of the first end face 13.111. The ends of the third first signal conductor 14.13 and the further signal conductor 14.14 which protrude onto the third first signal conductor contact surface 13.133 and the further signal conductor contact surface 13.134 of the further end face 13.112 are hidden in the view shown in FIG. 10 and, thus, not visible.

Now, a contact is established between the signal conductor contact surfaces 13.131-13.134 and the ends of the signal conductors 14.11-14.14. This contact is achieved using a tool such as a soldering iron, soldering torch, and the like. In the depiction according to FIG. 10 showing the first embodiment of the piezoelectric transducer 1 according to FIG. 1, one end of each of the three first signal conductors 14.11-14.13 is connected to exactly one of the three first signal conductor contact surfaces 13.131-13.133. The end of the further signal conductor 14.14 is connected to the further signal conductor contact surface 13.134.

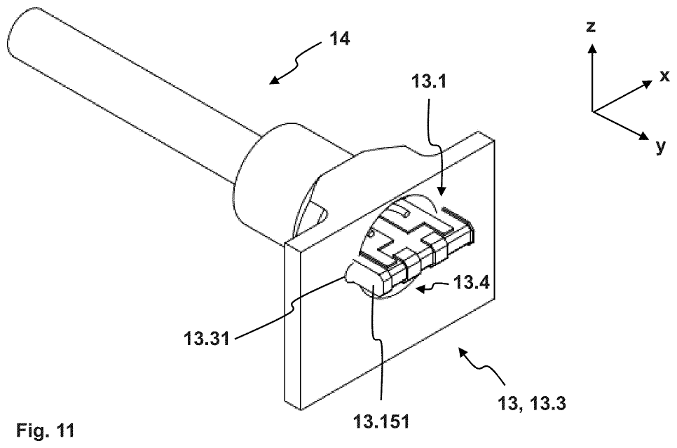

FIG. 11 schematically shows a third step of the assembly in which the support element 13.1 is inserted in the signal lead-through wall 13.3. The support element 13.1 comprises guiding elements 13.151, 13.152 formed as ridges that are inserted into groove-shaped holding elements 13.31, 13.32 of the signal lead-through wall 13.3. This insertion of the guiding element 13.151, 13.152 into the holding elements 13.31, 13.32 is achieved by pushing the support element 13.1 into the signal conductor opening 13.4 in the direction of the longitudinal axis y. The inserted support element 13.1 is retained in the signal lead-through wall 13.3 by the holding elements 13.31, 13.32.

FIG. 12 schematically shows a fourth step of the assembly in which the signal conductors 14.11-14.14 in contact with the signal conductor contact surfaces 13.131-13.134 are cast with casting compound 13.5. The casting compound 13.5 is applied through the signal conductor opening 13.4 to the signal conductors 14.11-14.14 and, further, in specific areas to the support element 13.1 and the circumference of the signal conductor opening 13.4. Thus, the signal conductor opening 13.4 is completely sealed by casting compound 13.5. The casting compound 13.5 is cured and/or set and the signal conductor opening 13.4 is sealed in a water-tight and gas-tight manner.

In addition, the cured and/or set casting compound 13.5 mechanically secures the support element 13.1 supported in the signal lead-through wall 13.3.

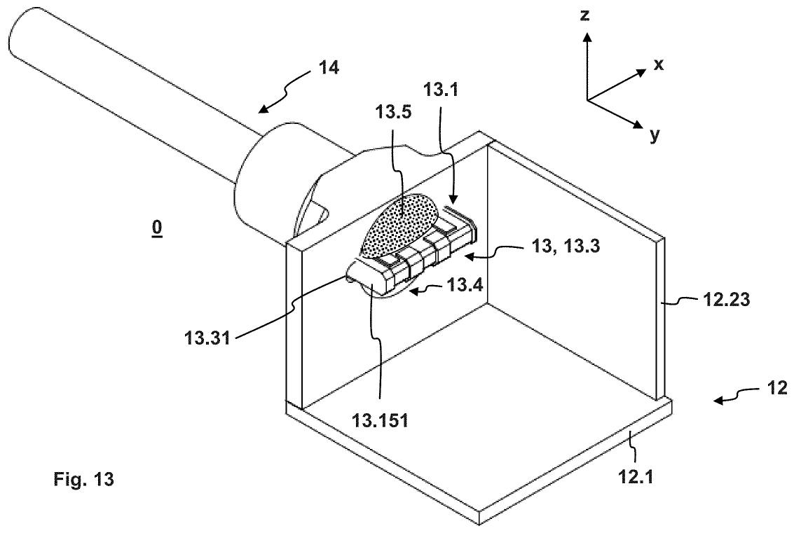

FIG. 13 schematically shows a fifth step of the assembly where the parts of the housing 12 are provided. These parts of the housing 12 provided are a housing base 12.1, three housing walls 12.21-12.23, and a housing cover 12.3. The housing base 12.1 and each of the three housing walls 12.21-12.23 is fastened to the signal lead-through wall 13.3 in a mechanically stable manner. This mechanically stable connection is achieved using a tool such as a welding tool, a soldering tool, and the like. Thus, the housing base 12.1, the three housing walls 12.21-12.23 and the signal lead-through wall 13.3 represent five side walls of the cuboid housing 12 that are connected to each other in a mechanically stable manner. This mechanically stable connection forms and defines the housing interior 12.0. The depictions according to FIGS. 13 to 15 showing the first embodiment of the piezoelectric transducer 1 according to FIG. 1 show the housing base 12.1, a second housing wall 12.22 and the signal lead-through wall 13.3. Not shown in the views according to FIGS. 13 to 15 are the first and third housing walls 12.21, 12.23. The only reason for not showing the first and third housing walls 12.21, 12.23 is to provide a view of the housing interior 12.0. However, the first and third housing walls 12.21, 12.23 are shown in the fully assembled view according to FIG. 17. Furthermore, the views according to FIGS. 13 to 15 show the housing 12 to which the housing cover 12.3 is not yet attached in a mechanically stable manner. Since the housing cover 12.3 is not yet installed, the housing 12 defines a housing opening. The housing interior 12.0 may be accessed from the environment 0 through the housing opening.

FIG. 14 schematically shows a sixth step of the assembly in which the transducer unit 11 is provided. The transducer unit 11 is inserted into the housing interior 12.0 and attached to the housing 12. Preferably, the transducer unit 11 is secured on the housing base 12.1 via the base body 11.3.

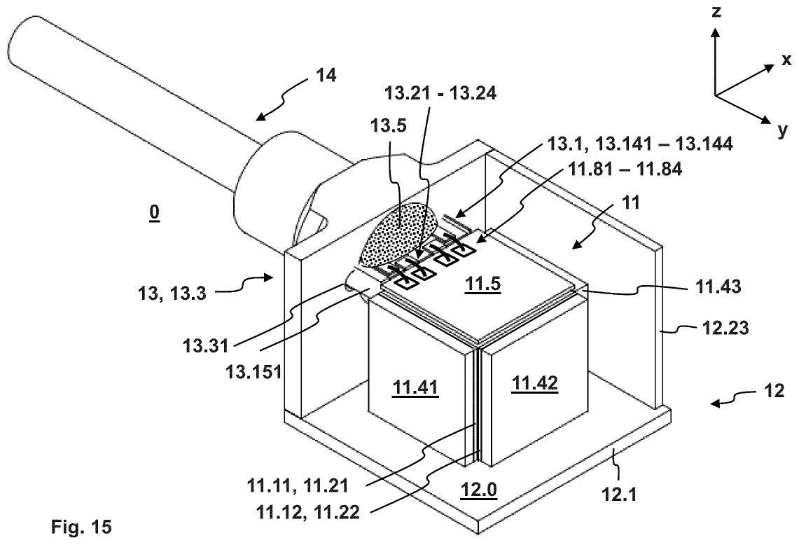

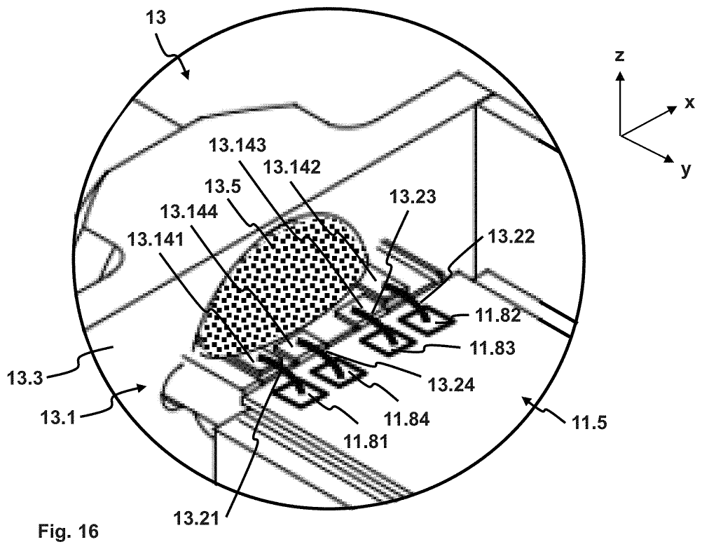

FIGS. 15 and 16 schematically show a seventh step of the assembly in which the connecting conductors 13.21-13.24 are provided. Contacts are established of the connecting conductors 13.21-13.24 with transducer unit contact surfaces 11.81-11.84 of the transducer element 11 and with connecting conductor contact surfaces 13.141-13.144 of the conducting paths 13.121-13.124 of the support element 13.1. These contacts are made by using a contacting tool such as a wire bonder, and the like. The housing interior 12.0 can be accessed by the contacting tool through the housing opening.

FIG. 16 schematically shows an enlarged view of a region of FIG. 15. In the views of FIGS. 15 and 16 showing the first embodiment of the piezoelectric transducer 1 according to FIG. 1, a first end of each of the three first connecting conductors 13.21-13.23 is in contact with exactly one of the three first transducer unit contact surfaces 11.81-11.83, and a second end of each of the three first connecting conductors 13.21-13.23 is in contact with exactly one of the three first connecting conductor contact surfaces 13.141-13.143. The first end of the further connecting conductor 13.24 is in contact with the further transducer unit contact surface 11.84, and the second end of the further connecting conductor 13.24 is in contact with the further connecting conductor contact surface 13.144.

FIG. 17 schematically shows an eighth step of the assembly in which the housing opening of the housing 12 is sealed in a water-tight and gas-tight manner by means of the housing cover 12.3. This sealing is achieved by material bonding such as welding, soldering, adhesive bonding, and the like. Thus, the housing cover 12.3 forms the sixth and last side wall of the housing 12 cuboid.

The assembly of the third embodiment of the piezoelectric transducer 1 according to FIG. 3 is schematically shown in the views according to FIGS. 18 to 22 and is described below:

FIG. 18 schematically shows a first step of the assembly in which parts of the housing 12, the signal lead-through 13 comprising the signal lead-through wall 13.3 and the support element 13.1 are provided. The parts of the housing 12 provided are a housing base 12.1, three housing walls 12.21-12.23 and a housing cover 12.3.

FIG. 18 schematically shows a second step of the assembly in which the housing base 12.1 and each of the three housing walls 12.21-12.23 are connected to the signal lead-through wall 13.3 in a mechanically stable manner. This mechanically stable connection is achieved by using a tool such as a welding tool, a soldering tool, and the like. Thus, five side walls of the housing 12 cuboid, i.e. the housing base, 12.1, the three housing walls 12.21-12.23 and the signal lead-through wall 13.3, are connected to each other in a mechanically stable manner. This mechanically stable connection defines the housing interior 12.0. FIGS. 18 to 21 show views of the third embodiment of the piezoelectric transducer 1 according to FIG. 3 showing the housing base 12.1, a second housing wall 12.22 and the signal lead-through wall 13.3. Not shown in the views according to FIGS. 18 to 21 are the first and third housing walls 12.21, 12.23. The only reason why the first and third housing walls 12.21, 12.23 are not shown is to provide a view of the housing interior 12.0. However, the first and third housing walls 12.21, 12.23 are shown in the fully assembled view according to FIG. 22. Furthermore, in the views as shown in FIGS. 18 to 21, the housing cover 12.3 is not yet connected to the housing 12 in a mechanically stable manner. Because the housing cover 12.3 is not yet installed, the housing 12 comprises a housing opening. The housing interior 12.0 is accessible from the environment 0 through the housing opening.

FIG. 18 schematically shows the second step of the assembly in which the support element 13.1 is attached to the signal lead-through wall 13.3. The arrangement of the support element 13.1 on the signal lead-through wall 13.3 is such that the signal conductor opening 13.4 and the through opening 13.4′ coincide with each other.

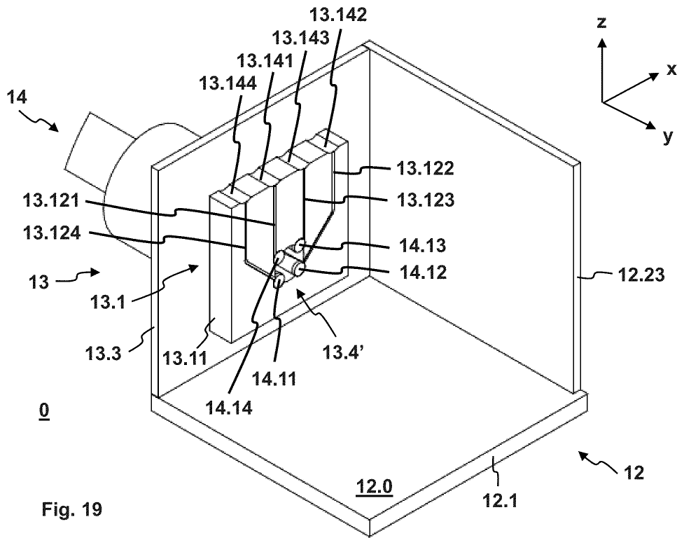

FIG. 19 schematically shows a third step of the assembly in which the signal cable 14 comprising the signal conductors 14.11-14.14 is provided. Ends of the signal conductors 14.11-14.14 are stripped of any insulation down to the bare metal. The stripped ends of the signal conductors 14.11-14.14 are inserted from the side of the environment 0 through the signal conductor opening 13.4. The stripped ends of the signal conductors 14.11-14.14 protrude through the signal conductor opening 13.4 into the through opening 13.4′ and protrude into the notch-shaped signal conductor contact surfaces 13.131-13.134.

FIG. 19 schematically shows a fourth step of the assembly in which the contacts between the ends of the signal conductors 14.11-14.14 and the signal conductor contact surfaces 13.131-13.134 are established. The contacts are achieved by using a tool such as a soldering iron, a soldering torch, and the like. FIG. 19 shows a view of the first embodiment of the piezoelectric transducer 1 according to FIG. 1 in which one end of each of the three first signal conductors 14.11-14.13 is connected to exactly one of the three first signal conductor contact surfaces 13.131-13.133. The end of the further signal conductor 14.14 is connected to the further signal conductor contact surface 13.134.

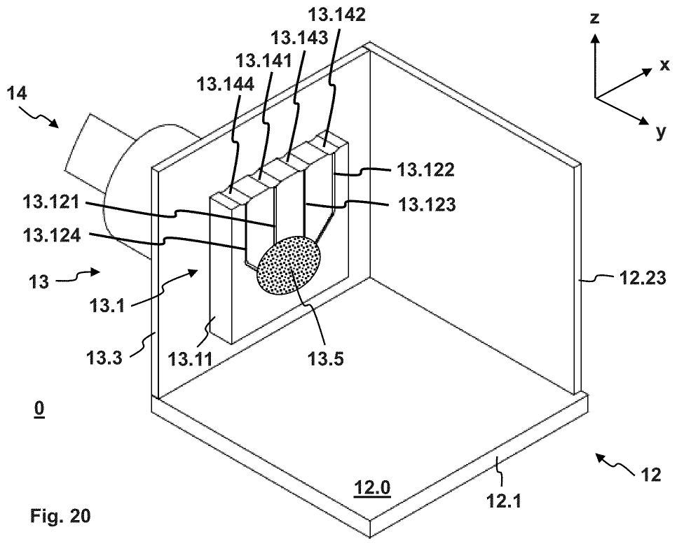

FIG. 20 schematically shows a fifth step of the assembly in which the signal conductors 14.11-14.14 in contact with the signal conductor contact surfaces 13.131-13.134 are cast with casting compound 13.5. The casting compound 13.5 is applied through the through-opening 13.4′ to the signal conductors 14.11-14.14 and in specific areas also to the support element 13.1 and the circumference of the through-opening 13.4′. In this way, the through opening 13.4′ is completely sealed with casting compound 13.5. The casting compound 13.5 is cured and/or set and the through-opening 13.4′ is sealed in a water-tight and gas-tight manner.

FIG. 21 schematically shows a sixth step of the assembly in which the transducer unit 11 is provided. The transducer unit 11 is introduced in the housing interior 12.0 and secured to the housing 12. Preferably, the transducer unit 11 is secured to the housing base 12.1 by the base body 11.3.

FIG. 21 schematically shows a seventh step of the assembly in which the connecting conductors 13.21-13.24 are provided. Contacts are established between the connecting conductors 13.21-13.24 and transducer unit contact surfaces 11.81-11.84 of the transducer element 11 and connecting conductor contact surfaces 13.141-13.144 of the conductor paths 13.121-13.124 of the support element 13.1. The contacts are achieved by using a contacting tool such as a wire bonder, and the like. The housing interior 12.0 may be accessed by the contacting tool through the housing opening.

FIG. 22 schematically shows an eighth step of the assembly in which the housing opening of the housing 12 is sealed by the housing cover 12.3 in a water-tight and gas-tight manner. The seal is achieved by material bonding such as welding, soldering, adhesive bonding, and the like. The housing cover 12.3 represents the sixth and last side face of the housing 12 cuboid.

While at least one presently preferred embodiment of the invention has been described using specific terms, such description is for illustrative purposes only, and it is to be understood that changes and variations may be made without departing from the spirit or scope of the following claims. This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal language of the claims.

### LIST OF REFERENCE NUMERALS

0 environment
1 piezoelectric transducer
11 transducer unit
11.11-11.13 piezo element
11.21-11.26 electrode
11.3 base body
11.41-11.43 seismic mass
11.5 converter unit
11.61, 11.62 insulation element
11.71, 11.72 compensation element
11.81-11.84 transducer unit contact surface
12 housing
12.0 housing interior
12.1 housing base
12.21-12.23 housing wall
12.3 housing cover
13 signal lead-through
13.1 support element
13.11 body
13.111, 13.112 end face
13.113 lateral surface
13.114 inner surface
13.121-13.124 conducting paths
13.131-13.134 signal conductor contact surface
13.141-13.144 connecting conductor contact surface
13.151, 13.152 guiding element
13.21-13.24 connecting conductor
13.3 signal lead-through wall
13.31, 13.32 holding element
13.4 signal conductor opening
13.4′ through opening
13.5 casting compound
13.6 signal lead-through flange
14 signal cable
14.11-14.14 signal conductor
14.2 cable insulation
14.3 protecting sheath
S1-S4 signal
x transverse axis
y longitudinal axis
z vertical axis

What is claimed is:

1. A piezoelectric transducer for measuring a measured variable in an environment of the piezoelectric transducer, the piezoelectric transducer comprising:
a transducer unit that includes a piezoelectric element, a first electrode and a further electrode, wherein the piezoelectric element is made of a piezoelectric material and generates polarization charges under the influence of the measured variable, wherein the piezoelectric element defines a first area connected to and directly contacting the first electrode, wherein the piezoelectric element defines a further area connected to and directly contacting the further electrode, wherein each of said first and further electrodes is configured to pick up the polarization charges generated by the piezoelectric element;
a housing which defines an interior surface and an exterior surface disposed opposite the interior surface and facing an external environment of the housing, wherein the interior surface is configured for enclosing the transducer unit in a water-tight and gas-tight manner that physically and electrically isolates the transducer unit from the external environment of the housing;
a signal lead-through that spans between the interior and exterior of the housing;
a support element connected to the signal lead-through, wherein the support element defines a first conducting path and a further conducting path, wherein the first conducting path is electrically connected to the first electrode, wherein the further conducting path is electrically connected to the further electrode, and wherein the signal lead-through is configured for transmitting the polarization charges as signals through the housing via the first and further conducting paths to the external environment of the housing;
a signal cable located at least partially in the external environment outside of the housing and including a first signal conductor and a further signal conductor; wherein the first signal conductor makes a contact with the first conducting path, wherein the further signal conductor makes a contact with the further conducting path.

2. The piezoelectric transducer according to claim 1, wherein the signal lead-through comprises a first connecting conductor and a further connecting conductor; wherein the transducer unit comprises a first transducer unit contact surface that is configured to carry the first signal; wherein the transducer unit comprises a further transducer unit contact surface that is configured to carry the further signal; wherein the first connecting conductor makes a contact with the first transducer unit contact surface; wherein the further connecting conductor makes a contact with the further transducer unit contact surface; wherein the first connecting conductor makes a contact with the first conducting path; and wherein the further connecting conductor makes a contact with the further conducting path.

3. The piezoelectric transducer according to claim 2, wherein the first conducting path comprises a first signal conductor contact surface and a first connecting conductor contact surface; wherein the further conducting path comprises a further signal conductor contact surface and a further connecting conductor contact surface; wherein the first signal conductor makes a contact with the first signal conductor contact surface; wherein the further signal conductor makes a contact with the further signal conductor contact surface; wherein the first connecting conductor makes a contact with the first connecting conductor contact surface, and wherein the further connecting conductor makes a contact with the further connecting conductor contact surface.

4. The piezoelectric transducer according to claim 2, wherein the first electrode is configured to carry the first signal, and wherein the further electrode is configured to carry the further signal; wherein the transducer unit comprises a first transducer unit contact surface that is configured to carry the first signal, and wherein the transducer unit comprises a further transducer unit contact surface that is configured to carry the further signal; wherein the first connecting conductor makes a contact with the first transducer unit contact surface and the first conducting path and is configured to carry the first signal; and wherein the further connecting conductor makes a contact with the further transducer unit contact surface and the further conducting path and is configured to carry the further signal.

5. The piezoelectric transducer according to claim 4, wherein the first signal conductor makes a contact with the first conducting path and is configured to carry the first signal; and wherein the further signal conductor makes contact with the further conducting path and is configured to carry the further signal.

6. The piezoelectric transducer according to claim 1, wherein the support element comprises a body made of electrically insulating material; and wherein each of the first and further conducting paths is patterned in an electrically conductive thin film applied directly to the body.

7. The piezoelectric transducer according to claim 6, wherein the first conducting path comprises a first signal conductor contact surface and a first connecting conductor contact surface, wherein the further conducting path comprises a further signal conductor contact surface and a further connecting conductor contact surface; wherein the support element comprises a first end face and a further end face; wherein the first signal conductor contact surface is arranged on the first end face and on the further end face, wherein the further signal conductor contact surface is arranged on the first end face and on the further end face; wherein the first connecting conductor contact surface is arranged on the first end face, and wherein the further connecting conductor contact surface is arranged on the first end face.

8. The piezoelectric transducer according to claim 1, wherein the signal lead-through defines a signal conductor opening and includes a casting compound; wherein the support element is disposed in the signal conductor opening and held in the signal conductor opening by the casting compound, which seals the signal conductor opening in a water-tight and gas-tight manner.

9. The piezoelectric transducer according to claim 8, wherein each of the first signal conductor and the further signal conductor defines a respective end that protrudes through the signal conductor opening; and wherein the casting compound covers the respective ends of the first signal conductor and the further signal conductor in the signal conductor opening while mechanically securing the support element inserted in the signal lead-through wall in a holding manner and sealing the signal conductor opening in a water-tight and gas-tight manner.

10. The piezoelectric transducer according to claim 6, wherein the first conductor path comprises a first conductor contact surface and a first connecting conductor contact surface, wherein the further conductor path comprises a further conductor contact surface and a further connecting conductor contact surface; wherein the support element comprises a first end face, a lateral surface and a through opening comprising an inner surface; in that the signal conductor contact surfaces are arranged on said inner surface; and in that the connecting conductor contact surfaces are arranged on said lateral surface.

11. The piezoelectric transducer according to claim 1, wherein the signal lead-through defines a signal conductor opening and a casting compound; wherein the support element defines a through-opening that is configured and disposed to coincide with the signal conductor opening; wherein the first signal conductor defines an end that protrudes through the signal conductor opening into the through-opening, wherein the further signal conductor defines an end that protrudes through the signal conductor opening into the through-opening; and wherein the casting compound covers the ends of the first and further signal conductors in the through-opening and seals the through-opening in a water-tight and gas-tight manner.

12. A procedure for the assembly of a piezoelectric transducer having a signal lead-through wall that defines an exterior and an interior disposed in opposition to the exterior, wherein the signal lead-through wall further defines a signal conductor opening that extends between the exterior and the interior, the procedure comprising the following steps:
from the exterior signal lead-through wall, inserting a signal cable through the signal conductor opening, wherein the signal cable includes a first signal conductor and a further signal conductor, wherein each of the first and further signal conductors defines a respective end that protrudes through the signal conductor opening;
positioning a support element in proximity of the ends of the first and further signal conductors that protrude through the signal conductor opening, wherein the support element is defined by a first end face and a further end face disposed in opposition to the first end face, wherein the first end face includes a first conducting path that terminates in a first signal conductor contact surface, wherein the further end face includes a further conducting path that terminates in a further signal conductor contact surface;
positioning the support element so that the end of the first signal conductor protrudes onto the first end face while the end of the further signal conductor protrudes onto the further end face;
arranging the support element in the signal conductor opening in such a way that the end of the first signal conductor is connected with the first signal conductor contact surface while the end of the further signal conductor is connected with the further signal conductor contact surface.

13. The procedure according to claim 12, wherein a holding element is defined in the signal lead-through wall; wherein the support element is provided with a guiding element that is configured to be in a complementary engaging relationship with the holding element of the signal lead-through wall; wherein during the step of arranging the support element in the signal conductor opening includes engaging the guiding element with the holding element; wherein a casting compound is applied to specific regions of the support element and the signal lead-through wall to cover the signal conductor contact surfaces and fill the signal conductor opening; wherein the casting compound is cured and/or set so that the signal conductor opening is closed in a water-tight and gas-tight manner with the support element inserted in the signal lead-through wall in a retaining and mechanically secured manner.

14. The procedure according to claim 12, further comprising:
incorporating the signal lead-through wall in a mechanically stable manner in to form a housing that defines a housing interior partially defined by the interior of the signal lead-through wall;
inserting a transducer element into the housing interior wherein the transducer unit comprises a first transducer unit contact surface and a further transducer unit contact surface;
securing the transducer element to the housing;
connecting a first connecting conductor with the first transducer unit contact surface, and connecting a further connecting conductor with the further transducer unit contact surface; and
connecting the first connecting conductor with the first conducting path, and connecting the further connecting conductor with the further conducting path.

15. A procedure for the assembly of a piezoelectric transducer having a transducer unit disposed in the interior of a housing formed partially by a signal lead-through wall and electrically connected to a signal cable disposed externally to the interior of the housing, which signal cable includes at least a first signal conductor and a further signal conductor, the procedure comprising the following steps:
providing an opening through the signal lead-through wall;
attaching the signal lead-through wall in a mechanically stable manner to form the housing interior;
disposing in the interior of the housing, a support element, which comprises a first end face, a second end face disposed in opposition to the first end face, a lateral surface disposed between and connecting the first end face and the second end face, and a through-opening comprising an inner surface, so that the through-opening coincides with the opening of the signal lead-through wall of the housing, wherein the first end face comprises a first conductor path and a further conductor path, wherein the first conductor path terminates in a first signal conductor contact surface, and wherein the further conductor path terminates in a further signal conductor contact surface;
disposing each of the first and further signal conductor contact surfaces on the inner surface of the support element;
securing the support element to the signal conductor opening in such a way that the signal conductor opening and the through opening coincide with each other;
inserting the signal conductors of the signal cable from the exterior of the housing through the signal conductor opening and the through opening and so that the ends of the signal conductors protrude through the signal conductor opening into the through opening and protrude onto the end faces of the support element; and
establishing an electrical contact between the end of the first signal conductor and the first signal conductor contact surface and establishing an electrical contact between the end of the further signal conductor and the further signal conductor contact surface.

16. The procedure according to claim 15, further comprising:
casting a casting compound onto the respective signal conductors in electrical contact with the respective signal conductor contact surfaces in the through opening;
curing and/or setting the casting compound in the through opening so that the through opening is sealed in a water-tight and gas-tight manner;
introducing the transducer element into the housing interior and securing the transducer element to the housing, wherein the transducer element includes a first transducer unit contact surface and a further transducer unit contact surface;
connecting a first connecting conductor with the first transducer unit contact surface, and connecting a further connecting conductor with the further transducer unit contact surface; and
connecting the first connecting conductor with the first conducting path of the support element, and connecting the further connecting conductor with the further conducting path of the support element.
